(19) United States
(12) Patent Application Publication
(10) Pub. No.: US 2024/0193078 A1
(43) Pub. Date: Jun. 13, 2024

(54) TECHNIQUES TO ALLOCATE MEMORY FOR IN-LINE OR IN-BAND ERROR CORRECTION CONTROL

(71) Applicant: Intel Corporation, Santa Clara, CA (US)

(72) Inventors: Vaibhav SHANKAR, Seattle, WA (US); Amir Ali RADJAI, Portland, OR (US); Jaishankar RAJENDRAN, Bangalore (IN); Evrim BINBOGA, Pleasanton, CA (US); Prashant KODALI, Portland, OR (US)

(21) Appl. No.: 18/078,984

(22) Filed: Dec. 11, 2022

(51) Int. Cl. G06F 12/02; G11C 29/54

(52) U.S. Cl. CPC G06F 12/023; G11C 29/54; G06F 2212/1044

(57) ABSTRACT

Examples include techniques associated with allocating memory capacity of a memory partitioned to include a first region arranged to include in-line or in-band error correction control (IBECC) memory and a second region arranged to include non-IBECC memory. The first and second regions can be re-sized based on usage of either region reaching a threshold.

### TECHNICAL FIELD

Examples described herein are generally related to techniques associated with in-line or in-band error correction control for data stored to a memory.

### BACKGROUND

A data protection technique that uses error correction control (ECC) memory is a type of data storage the utilizes ECC to detect and correct data corruption. In certain systems/applications having a low or no tolerance for errors, ECC memory is used. ECC is one way to add an extra layer of protection in terms of memory reliability. ECC memory can be deployed in workstations and servers using random access memory (RAM). Two examples of ECC memory are out-of-band ECC memory and in-line or in-band ECC memory. Out-of-band ECC memory uses an extra memory chip that is arranged to store parity data that is used to calculate error correction bits. In-band ECC (hereinafter referred to as “IBECC”) memory does not use an extra memory chip, rather ECC code is transmitted in-line or in-band via a memory channel such as a 16/32/64-bit memory channel. For IBECC memory some bits in the memory channel are used to transmit ECC data (e.g., parity bits). The bits used to transmit ECC data when using IBECC memory causes higher memory bandwidth consumption compared to storing data without ECC protection or at least without IBECC protection.

### BRIEF DESCRIPTION OF THE DRAWINGS

FIG. 1 illustrates an example computing platform.

FIG. 2 illustrates example process control block (PCB) structures.

FIG. 3 illustrates an example boot flow.

FIG. 4 illustrates an example first scheme.

FIG. 5 illustrates example second scheme.

FIG. 6 illustrates an example third scheme.

FIG. 7 illustrates an example first apparatus.

FIG. 8 illustrates an example first logic flow.

FIG. 9 illustrates an example first storage medium.

FIG. 10 illustrates an example second apparatus.

FIG. 11 illustrates an example second logic flow.

FIG. 12 illustrates an example second storage medium.

### DETAILED DESCRIPTION

As contemplated by this disclosure, bits used to transmit ECC data when using IBECC memory causes higher memory bandwidth consumption compared to storing data without ECC protection. In some observations of use of IBECC memory where all system memory utilized by applications supported by a computing platform is arranged as an IBECC memory, a performance penalty for these applications can be around 5% to 30% compared to storing data for these applications without the ECC protection. The performance penalty of an application when using IBECC memory may vary depending on workload type (severely penalizing applications which are memory access intensive), system memory configuration (e.g., memory ranks or channels) or type of memory technology (e.g., double data rate (DDR) vs low power DDR (LPDDR)).

Currently, when IBECC memory is enabled, all system memory utilized by applications supported by a computing platform is set to be an IBECC memory region. In other words, all applications storing data to the system memory will have to allocate memory bandwidth for ECC bits when storing data to system memory when IBECC memory is enabled. This allocation of memory bandwidth causes performance penalties for all these applications. This disclosure describes techniques for reducing performance penalties or overhead by enabling IBECC memory coverage for selective applications requesting additional memory reliability/protection. Applications that don't require or need additional memory reliability, will be able to opt out of IBECC memory coverage based on a partitioning of system memory into IBECC(protected)/non-IBECC(unprotected) regions and the IBECC/non-IBECC regions can be dynamically changed based on an overall system-wide demands for IBECC/non-IBECC by applications.

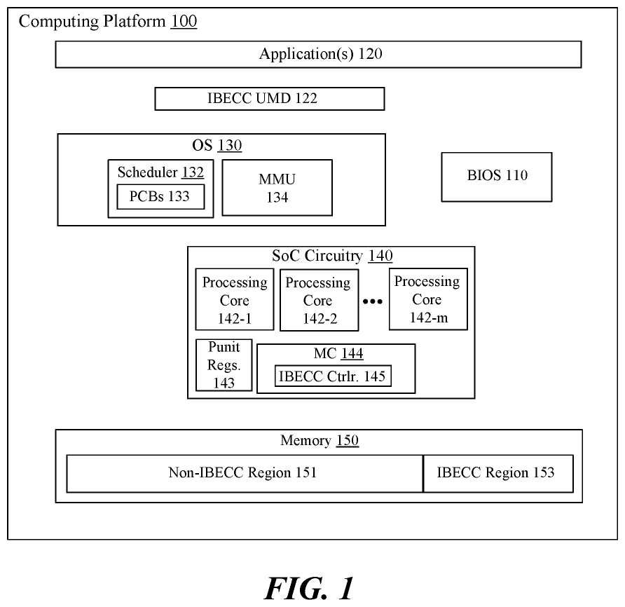

FIG. 1 illustrates an example computing platform 100. According to some examples, as shown in FIG. 1, computing platform 100 includes a basic input/output system (BIOS) 110, one or more application(s) 120, an IBECC user mode driver (UMD) 122, an operating system (OS) 130, system-on-chip (SoC) circuitry 140 or memory 150. BIOS 110, for example, can be arranged as a Unified Extensible Firmware Interface (UEFI) BIOS. For these examples, computing platform 100 can include, but is not limited to, a server, a server array or server farm, a web server, a network server, an Internet server, a workstation, a mini-computer, a main frame computer, a supercomputer, a network appliance, a web appliance, a distributed computing system, multiprocessor systems, processor-based systems, or combination thereof.

In some examples, OS 130 is shown in FIG. 1 as including a scheduler 132 and a memory management unit (MMU) 134. For these examples, scheduler 132 can be arranged to maintain process control blocks (PCBs) 133. PCBs 133, for example, serves as an OS process/task initialization structure having data/information pertaining to a particular process associated with an application from among application(s) 120. As described more below, scheduler 132 may generate PCBs 133 based on hints received from application(s) 120 through IBECC UMD 122. A hint to indicate a desired level of data reliability (e.g., IBECC or no IBECC) for a respective application from among application(s) 120. Also, as described more below, following an initial partitioning by BIOS 110 of memory 150 to include non-IBECC region 151 and IBECC region 153, MMU 134 facilitates allocation of these regions of memory 150 to application(s) 120. MMU 134 can also, based on monitored usage statistics for the allocated IBECC memory and non-IBECC memory regions, trigger a memory ballooning of either non-IBECC region 151 or IBECC region 153 to allow for a dynamic re-sizing of these regions maintained in memory 150.

According to some examples, as shown in FIG. 1, SoC circuitry 140 includes processing cores 142-1 to 142-m, where “m” is any positive whole integer greater than 1. Processing cores 122-1 to 122-m may include various commercially available processors, including without limitation an AMD® Zen®; ARM® application processor embedded and secure processors; Qualcomm® Snapdragon® processors; Intel® Atom®, Core i3, Core i5, Core i7, Xeon® or Xeon Phi® processors; and similar processors. Also, as shown in FIG. 1, SoC circuitry 140 includes a memory controller (MC 144). As described more below, an IBECC controller 145 of MC 144 may facilitate dynamic re-sizing of IEBCC coverage by a ballooning technique that causes a reallocation or sifting of amounts of memory included in respective non-IBECC region 151 or IBECC region 153. As briefly mentioned above, the ballooning technique can be triggered by MMU 134 based on usage statistics associated with these regions of memory 150. In some examples, one or more registers included in punit registers 143 may be used by MMU 134 to relay re-sizing information to IBECC controller 145 to cause the ballooning technique to be triggered.

While various examples described herein could use System-on-a-Chip or System-on-Chip (“SoC”) to describe a device or system having a processor and associated circuitry (e.g., I/O circuitry, processing cores, power delivery circuitry, memory controller circuitry, memory circuitry, etc.) integrated monolithically into a single integrated circuit (“IC”) die, or chip, the present disclosure is not limited in that respect. For example, in various examples of the present disclosure, a device, computing platform or computing system could have one or more processors (e.g., one or more processor cores) and associated circuitry (e.g., I/O circuitry, power delivery circuitry, memory controller circuitry, memory circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets could be physically and electrically coupled together by a package structure including, for example, various packaging substrates, interposers, interconnect bridges and the like. Also, these disaggregated devices can be referred to as a system-on-a-package (SoP).

Memory 150 can include volatile and/or non-volatile types of memory. In some examples, Memory 150 includes one or more dual in-line memory modules (DIMMs) that are arranged to include any combination of volatile or non-volatile memory. For these examples, the volatile and/or non-volatile memory included in memory 150 may operate in compliance with a number of memory technologies described in various standards or specifications, such as DDR3 (DDR version 3), JESD79-3F, originally released by JEDEC (Joint Electronic Device Engineering Council) in July 2012, DDR4 (DDR version 4), JESD79-4C, originally published in January 2020, DDR5 (DDR version 5), JESD79-5B originally published in September 2022, LPDDR3 (Low Power DDR version 3), JESD209-3C, originally published in August 2015, LPDDR4 (LPDDR version 4), JESD209-4D, originally published by in June 2021, LPDDR5 (LPDDR version 5), JESD209-5B, originally published by in June 2021), WIO2 (Wide Input/output version 2), JESD229-2 originally published in August 2014, HBM (High Bandwidth Memory), JESD235, originally published in October 2013, HBM2 (HBM version 2), JESD235C, originally published in January 2020, or HBM3 (HBM version 3), JESD238, originally published in January 2022, or other memory technologies or combinations of memory technologies, as well as technologies based on derivatives or extensions of such above-mentioned specifications. The JEDEC standards or specifications are available at www.jedec.org.

According to some examples, as mentioned above, memory 150 can include various types of volatile and/or non-volatile memory. Volatile types of memory may include, but are not limited to, dynamic random access memory (DRAM), static random access memory (SRAM), thyristor RAM (TRAM) or zero-capacitor RAM (ZRAM). Non-volatile types of memory may include byte or block addressable types of non-volatile memory having a 3-dimensional (3-D) cross-point memory structure that includes chalcogenide phase change material (e.g., chalcogenide glass) hereinafter referred to as “3-D cross-point memory”. Non-volatile types of memory may also include other types of byte or block addressable non-volatile memory such as, but not limited to, multi-threshold level NAND flash memory, NOR flash memory, single or multi-level phase change memory (PCM), resistive memory, nanowire memory, ferroelectric transistor random access memory (FeTRAM), magnetoresistive random access memory (MRAM) that incorporates memristor technology, spin transfer torque MRAM (STT-MRAM), or a combination of any of the above.

Although not shown in FIG. 1, computing platform 100 may include additional components that facilitate the operation of the computing platform 100. For example, various network and/or internal communication interfaces and associated interconnects can communicatively couple the elements shown in FIG. 1 to each other or to elements on other computing platforms.

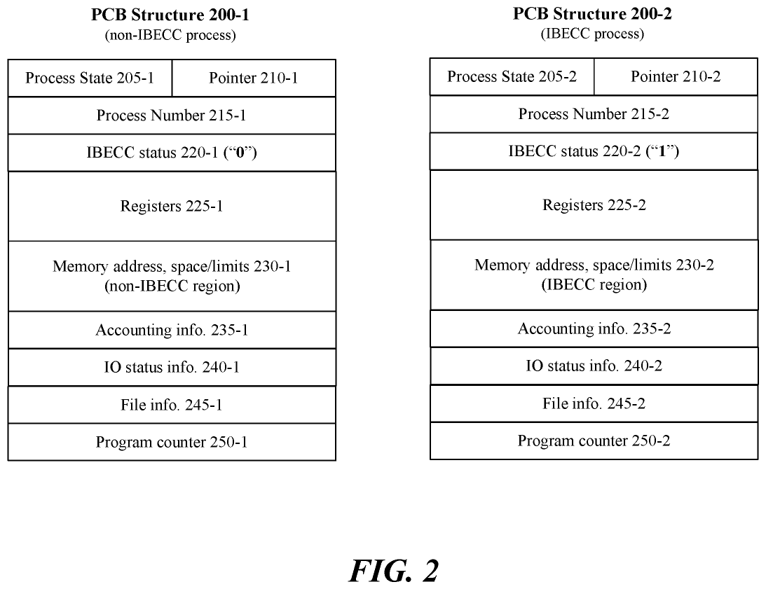

FIG. 2 illustrates example PCB structures 200-1 and 200-2. In some examples, logic and/or features of an OS for a computing platform such as scheduler 132 of OS 130 for computing platform 100 may populate PCB structures 200-1 and 200-2 to include information for processes running on or supported by the computing platform. The processes, for example, associated with application(s) 120. For a given PCB structure 200, as shown in FIG. 2, the information includes a process state 205 field to indicate whether the process is running, waiting, sleeping, zombie, stopped, etc. The information also includes a pointer 210 field that references a parent process and a process number 215 field that indicates a process identification (PID) number. As mentioned more below, the information also includes an IBECC status 220 field that indicates whether an application has hinted/indicated whether IBECC memory is desired for storing data associated with the process. The information also includes a registers 225 field that indicates contents of all process-centric registers (e.g., accumulators or stack pointers). The information also includes a memory address, space/limits 230 field to indicate memory management information to include memory address, space/limits associated with a non-IBECC region or an IBECC region allocated to the process. The information also includes an accounting information field 235 that can indicate a central processing unit (CPU) used, clock time elapsed since start, or time limits. The information also includes an IO status information 240 field that can indicate I/O devices allocated to the process and/or a list of open files. The information also includes a file information 245 field that indicates files opened or modified by the process. The information also includes a program counter 250 field that can indicate a location of a next instruction to execute for the process.

According to some examples, as shown in FIG. 2, example PCB structure 200-1 has an IBECC status 220-1 field bit value of “0”. For these examples, an IBECC UMD such as IBECC UMD 122 may have received meta data from an application from among application(s) 120 that indicates that the increased reliability associated with using IBECC memory is not needed or requested and thus the process associated with the application is a non-IBECC process. IBECC UMD 122 may notify OS 130 of this non-IBECC status and logic and/or features of the OS 130 (e.g., scheduler 132) may de-assert a 1-bit flag in the IBEC status 220-1 field to represent a value of “0” and to indicate the non-IBECC status. Based on the non-IBECC status indicated by the value of “0” and based on information included in the memory address, space/limits 230-1 field, logic and/or features of OS 130, such as MMU 134 can, in cooperation with logic/and or features of MC 144, cause a portion of memory 150 included in non-IBECC region 151 to be allocated for use by this non-IBECC process.

In some examples, as shown in FIG. 2, example PCB structure 200-2 has an IBECC status 220-2 field bit value of “1”. For these examples, IBECC UMD 122 may have received meta data from an application indicating that the increased reliability associated with using IBECC memory is needed/requested and thus the process associated with the application is an IBECC process. IBECC UMD 122 may notify OS 130 of this IBECC status and logic and/or features of the OS 130 (e.g., scheduler 132) may assert a 1-bit flag in the IBEC status 220-1 field to represent a value of “1” and to indicate the IBECC status. Based on the IBECC status indicated by the value of “1” and based on information included in the memory address, space/limits 230-2 field, logic and/or features of OS 130, such as MMU 134 can, in cooperation with MC 144 at SoC circuitry 140, cause a portion of memory 150 included in IBECC region 153 to be allocated for use by this IBECC process.

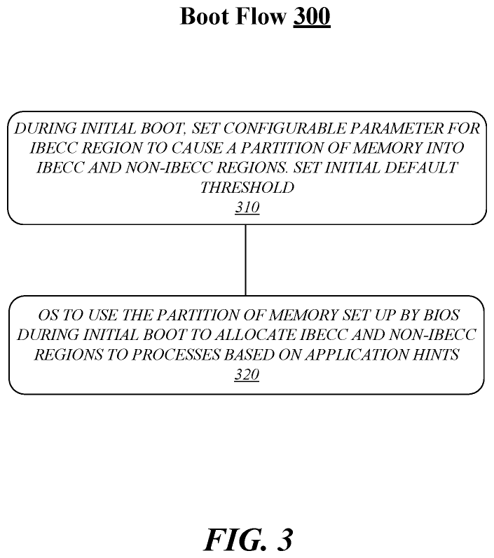

FIG. 3 illustrates an example boot flow 300. According to some examples, boot flow 300 can be an example of actions taken by a BIOS such as BIOS 110 and an OS such as OS 130 during a boot or initial startup of a computing platform such as computing platform 100.

In some examples, at 310, during initial boot, BIOS 110 sets a configuration parameter for an IBECC region to cause a partition of memory 150 into IBECC region 153 and non-IBECC region 151. For these examples, the set configuration parameter establishes a memory capacity starting point for an IBECC region. For example, memory 150 has a total memory capacity of 1 gigabyte (GB) for use as non-IBECC and IBECC memory. This initially set configuration parameter may partition a portion of memory 150 for use as IBECC memory according to an initial default IBECC threshold that can be based on an IBECC minimum granularity. The IBECC minimum granularity, for example, is a minimum increment that IBECC memory can be increased/inflated or decreased/deflated in memory 150. For example, an IBECC minimum granularity can be 256 megabytes (MBs). So, with a memory capacity of 1 GB, memory 150 can be partitioned to provide 750 MBs to non-IBECC region 151 and 250 MBs to IBECC region 153.

In some examples, at 320, logic and/or features of OS 130 can use the partition of memory 150, set by BIOS 110 during initial boot of computing platform 100, to allocate IBECC and Non-IBECC regions to processes based on application hints. For these examples, the logic and/or features of OS 130 such as scheduler 132 may populate information included in PCBs 133 for each process and provide PCBs 133 to MMU 134. MMU 134 may use these PCBs (e.g., in example format of PCB structure 200) to allocate memory addresses mapped to either non-IBECC region 151 or IBECC region 153 of memory 150. As describe more below, MMU 134 can work in collaboration with logic and/or features of MC 144 such as IBECC controller 145 to enable a dynamic re-size of IBECC coverage provided by non-IBECC region 151 or IBECC region 153 based on subsequent requests/hints by application(s) 120 to use or not use IBECC memory, the subsequent requests to be made while computing platform 100 is in operation.

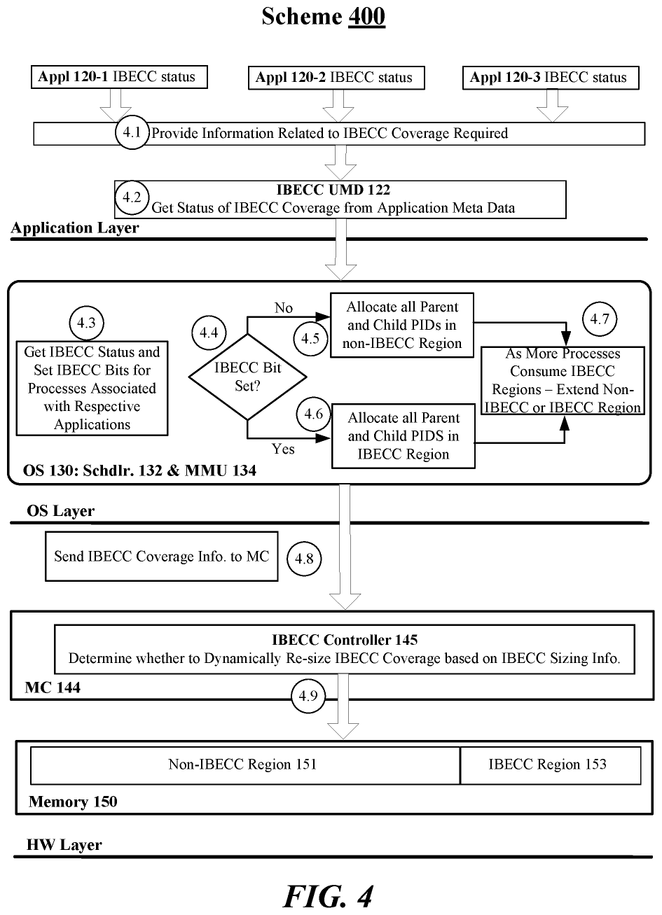

FIG. 4 illustrates an example scheme 400. In some examples, scheme 400 shows an example of a method to selectively provide IEBCC coverage for applications based on information provided by the applications and also to determine whether to dynamically re-size IEBCC or non-IEBCC regions maintained in a memory. For these examples, as shown in FIG. 4, scheme 400 can be implemented by elements of computing platform 100 such as, but not limited to, application(s) 120, IBECC UMD 122, logic and/or features of OS 130 including scheduler 132, IBECC controller 145 of MC 144, or memory 150, as described above and shown in FIG. 1.

According to some examples, at 4.1, applications 120-1 to 120-3 may separately provide information related to IBECC coverage. For these examples, the information can be included in meta data and indicates a level of data reliability requested or needed. An indicated high level of reliability, for example, indicates IBECC coverage is requested. Meanwhile, an indicated low level of reliability, for example, indicates no IBECC coverage is requested or needed.

In some examples, at 4.2, IBECC UMD 122 gets a status of IBECC coverage from each respective application's meta data. For these examples, as shown in FIG. 4, IBECC UMD 122 is considered with applications 120-1 to 120-3 as being part of an application layer for scheme 400. IBECC UMD 122, as part of an application layer, can be arranged to communicate with elements of OS 130 (e.g., scheduler 132) via an application programming interface (API). IBECC UMD 122, for example, can make a system (sys) call to OS 130 via the API to provide the status of IBECC coverage for each respective application to OS 130.

According to some examples, at 4.3, logic and/or features of OS 130 such as scheduler 132 gets IBECC coverage status and sets an IBECC bit for processes associated with respective applications. For these examples, scheduler 132 gets IBECC coverage status from IBECC UMD 122 and sets the IBECC bit included in the IBECC status 220 field of example PCB structure 200 for processes associated with respective applications 120-1 to 120-3 to indicate each application's requested IBECC coverage.

In some examples, at 4.4, logic and/or features of OS 130 such as MMU 134 determines whether a respective application's PCB structure has the IBECC bit set in the IBECC status 220 field. If not set (value of “0”), scheme 400 moves to 4.5. If set (value of “1”), scheme 400 moves to 4.6.

According to some examples, at 4.5, since MMU 134 has determined that the IBECC bit has not been set for a particular application, MMU 134 then causes all parent and child PIDs for that particular application to be allocated memory capacity included in a non-IBECC region of memory. For example, if a PCB structure in the example format PCB structure 200 is associated with application 120-1 and IBECC status 220 field for that PCB structure is not set, then MMU 134 causes memory capacity to be included in non-IBECC region 151 of memory 150 for all parent and child processes or PIDs assigned to application 120-1.

In some examples, at 4.6, since MMU 134 has determined that the IBECC bit has been set for a particular application, MMU 134 then causes all parent and child PIDs for that particular application to be allocated memory capacity included in an IBECC region of memory. For example, if a PCB structure in the example format PCB structure 200 is associated with application 120-2 and IBECC status 220 field for that PCB structure is set, then MMU 134 causes memory capacity to be included in IBECC region 153 of memory 150 for all parent and child processes or PIDs assigned to application 120-2.

In some examples, at 4.7, logic and/or features of OS 130 such as MMU 134 may monitor or track PIDs associated with application(s) 120 using non-IBECC or IBECC regions. As more processes or PIDs associated with applications consume memory capacity of non-IBECC or IBECC regions, MMU 134 can decide to send information to MC 144 to cause an extension or re-sizing of non-IBECC region 151 or IBECC region 153. Examples of how OS 130 and/or MMU 134 can track usage of IBECC and non-IBECC regions by processes associated with application(s) 120 is described in more detail below.

According to some examples, at 4.8, logic and/or features of OS 130 such as MMU 134 sends IBECC coverage information to MC 144. For these examples, MC 144 and memory 150, as shown in FIG. 4, are included in a hardware (HW) layer of scheme 400. The IBECC coverage information, for example, may be based on information included in the memory address, space/limits 230 field of a PCB structure in the example format PCB structure 200 that indicates memory addresses mapped to either non-IBECC region 151 or IBECC region 153 and space/limits to allocated memory capacity. Also, the IBECC coverage information may also include IBECC/Non-IBECC sizing information that is based on tracked usage by OS 130 as briefly mentioned above and as will be described in more detail below.

In some examples, at 4.9, logic and/or features of MC 144 such as IBECC controller 145 can dynamically determine whether to re-size non-IBECC or IBECC coverage based on the sizing information received from OS 130. Re-sizing of non-IBECC or IBECC coverage can include use of a ballooning technique to expand a first region, yet deflate the second region to accommodate expansion of the first region. For example, sizing information received from OS 130 can indicate that IBECC region 153 needs to be re-sized to accommodate a greater amount of IBECC coverage as per requests received from application(s) 120 during an operational state of computing platform 100. Memory capacity will first need to be reduced for non-IBECC region 151 in order to accommodate an increase in memory capacity for IBECC region 153 to implement this re-sizing to accommodate the greater amount of IBECC coverage. Scheme 400 may then come to an end.

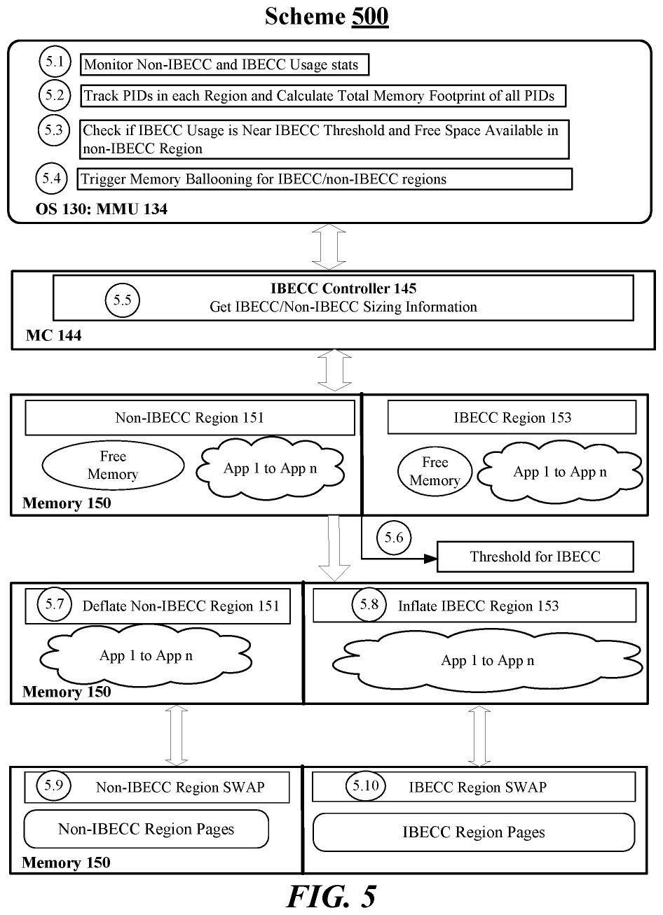

FIG. 5 illustrates an example scheme 500. According to some examples, scheme 500 shows example actions associated with implementing a memory ballooning technique to dynamically re-size IBECC coverage at a memory for use by applications during an operational state of a computing platform. For these examples, actions shown for scheme 500 can be implemented by logic and/or features of OS 130 such as, but not limited to MMU 134, logic and/or features of MC 144 such as IBECC controller 145 or memory 150 as described above and shown in FIG. 1.

In some examples, at 5.1, logic and/or features of OS 130 such as MMU 134 monitors non-IBECC and IBECC usage statistics. For example, OS 130 may use OS counters to track “used” and “free” memory in non-IBECC region 151 and IBECC region 153.

According to some examples, at 5.2, MMU 134 can track PIDs in each region and calculate a total memory footprint of all PIDs. For these examples, “used” memory can be calculated from memory allocated to all processes for a given region. In some examples, process allocated memory size for each process=size of (an ECC code segment+data segment+Stack+Heap). Also, “free” memory can be calculated by subtracting “used” memory from a total memory capacity allocated to the given region.

In some examples, at 5.3, MMU 134 checks if IBECC usage is near an IBECC threshold and free space is available in a non-IBECC region. For example, the IBECC threshold may be the initial default threshold of 250 MBs that was set by BIOS 110 for IBECC region 153 of memory 150 during initialization of computing platform 100 as mentioned above for flow 300. In other examples, the IBECC threshold may have been previously re-sized to a higher memory capacity than the initial default threshold of 250 MBs. MMU 134 also check to see if free space is available in non-IBECC region 151 of memory 150 to provide additional memory capacity to IBECC region 153.

According to some examples, at 5.4, if MMU 134 determines that IBECC usage is near to the IBECC threshold and this nearness causes a trigger to memory ballooning for IBECC/Non-IBECC. The trigger, for example, may be caused by IBECC/Non-IBECC sizing information that is sent to IBECC controller 145 to indicate how much IBECC region 153 needs to be re-sized to accommodate current IBECC usage. The amount of re-sizing, for example, may be based on the IBECC minimum granularity set by BIOS 110 for IBECC region 153 of memory 150 during initialization of computing platform 100 as mentioned above for flow 300. The re-sizing can also be based on the determined amount of available free space in non-IBECC region 151.

In some examples, at 5.5, logic and/or features of MC 144 such as IBECC controller 145 gets the IBECC/Non-IBECC sizing information sent from MMU 114.

According to some examples, at 5.6, the IBECC/non-IBECC sizing information indicates to IBECC controller 145 that all or nearly all free memory included in IBECC region 153 is consumed or will soon be consumed by IBECC requesting applications 1 to n, where “n” is any whole integer greater than 1. For this example, consumption of all free memory in IBECC region 153 brings IBECC usage near the IBECC threshold. The IBECC/non-IBECC sizing information also indicates to IBECC controller 145 whether sufficient free space is available in non-IBECC region 151 to at least re-size or inflate IBECC region 153 by at least the IBECC minimum granularity (e.g., 256 MBs).

In some examples, at 5.7, IBECC controller 145 causes non-IBECC region 151 to be deflated by removing at least the IBECC minimum granularity of non-IBECC region 151's free space and make this deflated memory capacity (e.g., 256 MBs) available to inflate IBECC region 153's memory capacity. The remaining “used” capacity at non-IBECC region 151 should be adequate to support memory capacity allocated to those non-IBECC requesting applications 1 to n. Although not shown in FIG. 5, non-IBECC region 151 may also have a non-IBECC threshold that can limit how much non-IBECC region 151 can be deflated to accommodate an inflation of IBECC region 153. The non-IBECC threshold, for example, can be set to 256 MBs.

According to some examples, at 5.8, IBECC controller 145 causes IBECC region 153 to be inflated. In other words, IBECC region 153's memory capacity is dynamically re-sized upward by at least the IBECC minimum granularity by reallocating the free memory capacity previously included in non-IBECC region 151 to IBECC region 153.

In some examples, at 5.9, IBECC controller 145 determines that the IBECC/non-IBECC sizing information sent from MMU 134 indicates that an insufficient amount of memory capacity is free in non-IBECC region 151. For these examples, IBECC controller 145 can cause a non-IBECC region swap partition to be created in memory 150. Responsive to insufficient free memory capacity in non-IBECC region 151, IBECC controller 145 may push least recently used (LRU) non-IBECC region 151 pages associated with applications requesting non-IBECC coverage to the non-IBECC region swap partition. At least a memory capacity equal to the IBECC minimum granularity is needed for these LRU pages pushed to the non-IBECC region swap partition.

According to some examples, at 5.10, IBECC controller 145 causes the memory addresses associated with the pages placed in the non-IBECC region swapped into IBECC region 153's IBECC region swap region to be reclaimed by IBECC region 153. In other words, memory addresses for those reclaimed pages are now included in IBECC region 153. Scheme 500 may then come to an end.

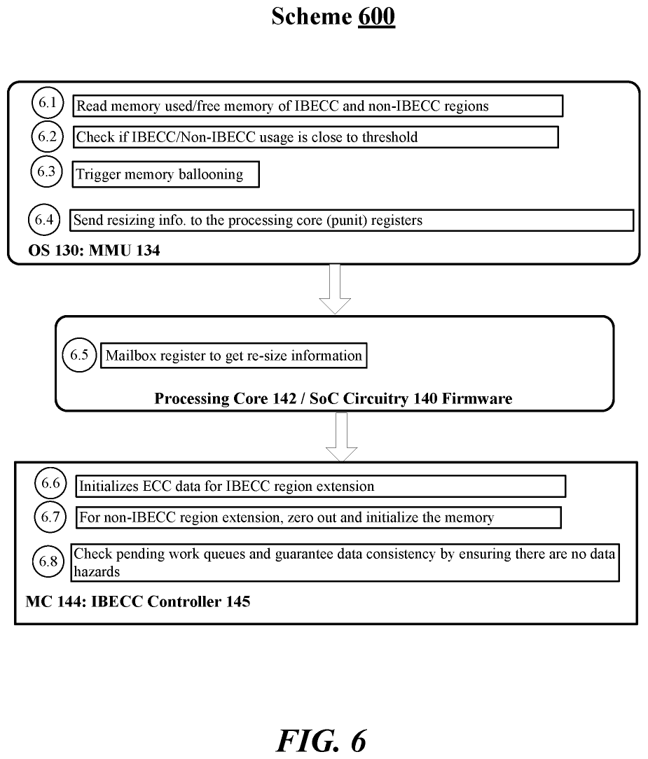

FIG. 6 illustrates an example scheme 600. According to some examples, scheme 600 shows another example of actions taken to dynamically re-size memory capacity allocated to non-IBECC and IBECC regions of a memory for use by applications requesting or not requesting IBECC coverage. For these examples, actions shown for scheme 600 can be implemented by logic and/or features of OS 130 such as MMU 134, processing core 142/SoC circuitry 140 firmware, or logic and/or features of MC 144 such as IBECC controller 145 as described above and shown in FIG. 1. Examples are not limited to these elements of computing platform 100.

According to some examples, at 6.1, MMU 134 reads memory used/free memory of IBECC and non-IBECC regions. For these examples, MMU 134 reads memory used/free memory for IBECC region 153 and for non-IBECC region 151 to track process memory footprints associated with applications requesting IBECC or non-IBECC coverage. As mentioned above, a memory footprint for a process equals a size of (an ECC code segment=data segment+Stack+Heap).

In some examples, at 6.2, MMU 134 checks to see if IBECC/Non-IBECC usage is close to an IBECC threshold or to a non-IBECC threshold. For these examples, MMU 134 is tracking both thresholds to determine which region to inflate and which region to deflate.

According to some examples, at 6.3, MMU 134 triggers memory ballooning based on IBECC/Non-IBECC usage being near a threshold. For these examples, if IBECC usage is near the IBECC threshold, then memory ballooning to inflate IBECC region 153 and deflate IBECC region 151 is triggered. If non-IBECC usage is near to the non-IBECC threshold, then memory ballooning to inflate non-IBECC region 151 and deflate IBECC region 153 is triggered.

In some examples, at 6.4, MMU 134 sends re-sizing information to the processing core (punit) registers at SoC circuitry 140. For these examples, sending re-sizing information to punit registers 143 at SoC circuitry 140 is an example method to relay re-sizing information between MMU 134 and logic and/or features of MC 144 such as IBECC controller 145.

According to some examples, at 6.5, punit registers 143 can be arranged to include a mailbox register to cause processing core 142/SoC circuitry 140 firmware to get re-sizing information from MMU 134. For these examples, the re-sizing information includes memory address ranges of memory 150 to be included in memory ballooning to re-size non-IBECC/IBECC regions 151/153.

In some examples, at 6.6, if the memory ballooning includes inflating IBECC region 153, processing core 142/SoC circuitry 140 firmware sends information to IBECC controller 145 to cause an ECC storage initiation at the memory address ranges indicate in the re-sizing information received from MMU 134.

According to some examples, at 6.7, if the memory ballooning includes inflating non-IBECC region 151, processing core 142/SoC circuitry 140 firmware sends information to IBECC controller 145 to zero out pages and initialize those memory addresses for non-IBECC coverage.

In some examples, at 6.8, MC 144 can check pending work queues and guarantee data consistency by ensuring there are no data hazards. For these examples, data destined to be stored in non-IBECC region 151 may be in a work queue for a process and a memory address for that data may be selected for adding to IBECC region 153's memory capacity. MC 144 may prevent that memory address from being added to IBECC region 153 as the data may be deleted during the ECC storage initiation. Preventing the memory address from being added avoids the data hazard of deleting data sent by the process that was allocated that memory address. Scheme 600 may then come to an end.

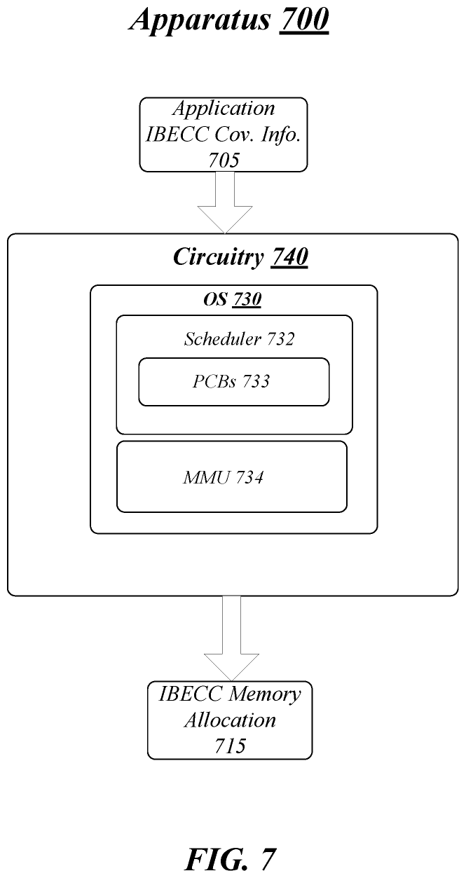

FIG. 7 illustrates an example apparatus 700. Although apparatus 700 shown in FIG. 7 has a limited number of elements in a certain topology, it may be appreciated that the apparatus 700 may include more or less elements in alternate topologies as desired for a given implementation.

According to some examples, apparatus 700 may be supported by circuitry 740 and apparatus 700 may be located as part of circuitry included in SoC circuitry of a computing platform, such as one or more processing cores 142 of SoC circuitry 140 of computing platform 100. Circuitry 740 may be arranged to execute an operating system 730 that includes a scheduler 732 and an MMU 734 that may be arranged to operate in a similar manner as described above for OS 130 that includes scheduler 132 and MMU 134.

In some examples, scheduler 732 may be a logic and/or feature of OS 730 executed by circuitry 740 to receive information from an application to indicate that data used or generated by a process associated with the application is to be stored in IBECC memory. The received information, for example, received in application IBECC coverage information 705. Scheduler 732 can then generate, based on the information from the application, a PCB for the process, the PCB to include a field to indicate the data used or generated by the process is to be stored in a first region of a memory arranged to provide IBECC memory. The generated PCB, for example, can be maintained by scheduler 732 among PCs 733 and can be in the format of example PCB structure 200 for which the IBECC status field indicates that the data is to be stored in the first region of the memory arranged to provide IBECC memory.

According to some examples, MMU 734 may be a logic and/or feature of OS 730 executed by circuitry 740 to cause a portion of memory capacity included in the first region of the memory to be allocated to the process. For example, Scheduler 732 can also include a second field in the generated PCB to indicate a memory address and size information for the portion of memory capacity to be allocated to the process. MMU 734 can cause the allocation of memory capacity by sending the memory address and size information to a memory controller for the memory to cause the portion of memory capacity to be allocated to the process.

Included herein is a set of logic flows representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware examples, a logic flow can be implemented by computer executable instructions stored on at least one non-transitory computer readable medium or machine readable medium, such as an optical, magnetic or semiconductor storage. The examples are not limited in this context.

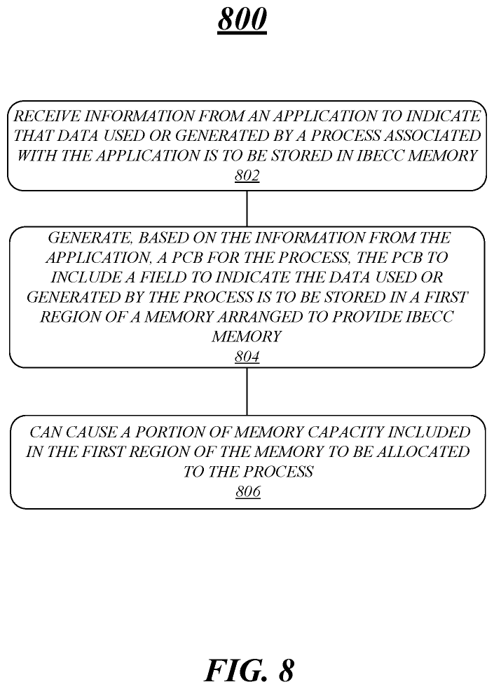

FIG. 8 illustrates an example logic flow 800. Logic flow 800 can be representative of some or all of the operations executed by one or more logic, features, or devices described herein, such as logic and/or features of OS 730 supported by circuitry 740 included in apparatus 700. More particularly, logic flow 800 can be implemented by one or more of scheduler 732 or MMU 734.

In some examples, as shown in FIG. 8, logic flow 800 at block 802 can receive information from an application to indicate that data used or generated by a process associated with the application is to be stored in IBECC memory. For these examples, scheduler 732 can receive the information from the application.

According to some examples, as shown in FIG. 8, logic flow 800 at block 804 can generate, based on the information from the application, a PCB for the process, the PCB to include a field to indicate the data used or generated by the process is to be stored in a first region of a memory arranged to provide IBECC memory. For these example, scheduler 732 can generate the PCB, e.g., using the example format of PCB structure 200.

In some examples, as shown in FIG. 8, logic flow 800 at block 806 can cause a portion of memory capacity included in the first region of the memory to be allocated to the process. For these examples, MMU 734 can cause the portion of memory capacity to be allocated to the process.

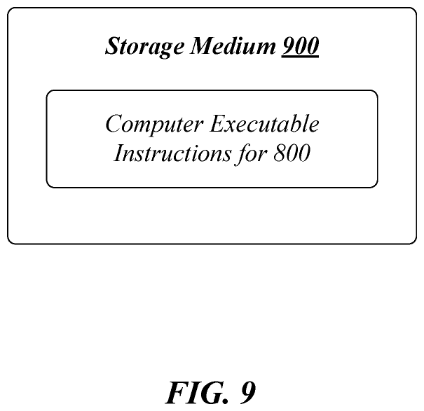

FIG. 9 illustrates an example of a storage medium. As shown in FIG. 9, the storage medium includes a storage medium 900. The storage medium 900 may comprise an article of manufacture. In some examples, storage medium 900 can include any non-transitory computer readable medium or machine readable medium, such as an optical, magnetic or semiconductor storage. Storage medium 900 can store various types of computer executable instructions, such as instructions to implement logic flow 800. Examples of a computer readable or machine readable storage medium can include any tangible media capable of storing electronic data, including volatile memory or non-volatile memory, removable or non-removable memory, erasable or non-erasable memory, writeable or re-writeable memory, and so forth. Examples of computer executable instructions can include any suitable type of code, such as source code, compiled code, interpreted code, executable code, static code, dynamic code, object-oriented code, visual code, and the like. The examples are not limited in this context.

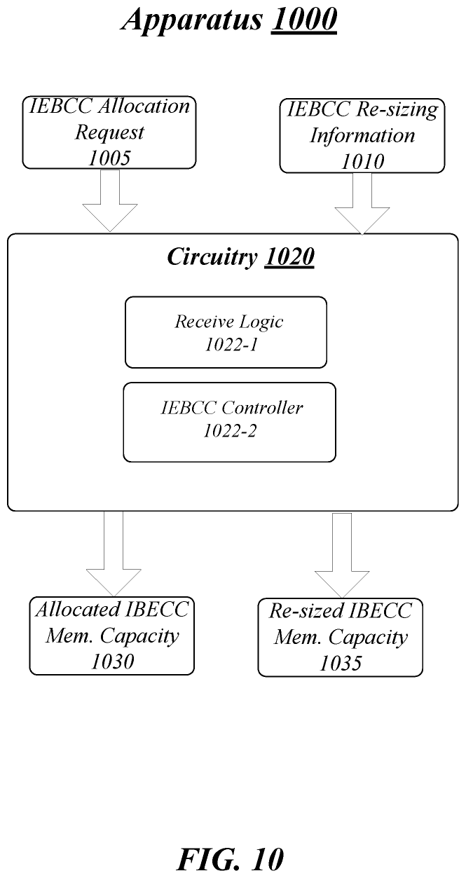

FIG. 10 illustrates an example apparatus 1000. Although apparatus 1000 shown in FIG. 10 has a limited number of elements in a certain topology, it may be appreciated that the apparatus 1000 can include more or less elements in alternate topologies as desired for a given implementation.

According to some examples, apparatus 1000 can be supported by circuitry 1020 and apparatus 1000 can be a memory controller included in SoC circuitry of a computing platform, such as MC 144 of SoC circuitry 140 of computing platform 100. Circuitry 1020 may be arranged to execute one or more software or firmware implemented logic, components, agents, modules, or controllers 1022-α (e.g., implemented, at least in part, by a memory controller to a memory). It is worthy to note that “α” and “b” and “c” and similar designators as used herein are intended to be variables representing any positive integer. Thus, for example, if an implementation sets a value for α=2, then a complete set of software or firmware for logic, components, agents, modules or controllers 1022-α can include 1022-1, or 1022-2. Also, at least a portion of “logic” or a “controller” can be software/firmware stored in computer-readable media, or may be implemented, at least in part in hardware and although the logic is shown in FIG. 10 as discrete boxes, this does not limit logic to storage in distinct computer-readable media components (e.g., a separate memory, etc.) or implementation by distinct hardware components (e.g., separate processors, processor circuits, cores, application specific integrated circuits (ASICs) or field programmable gate arrays (FPGAs)).

In some examples, apparatus 1000 can include a receive logic 1022-1. Receive logic 1022-1 can be a logic and/or feature executed by circuitry 1020 to receive an allocation request from an OS to allocate IBECC memory for data used or generated by a process associated with an application. For these examples, the allocation request can be included in IBEC allocation request 1005.

According to some examples, apparatus 1000 can include an IBECC controller 1022-2. IBECC controller 1022-2 can be a logic and/or feature executed by circuitry 1020 to allocate a portion of memory capacity included in a first region of a memory arranged to provide the IBECC memory to the process based on the allocation request. For this example, a second region of the memory is arranged to not provide IBECC memory or is arranged to provide non-IBECC memory. The allocated portion of memory capacity, for example, can be indicated in allocated IBECC memory capacity 1030.

In some examples, receive logic 1022-1 can also receive re-sizing information from the OS to indicate a re-sizing of the memory capacity included in the first region of the memory. For these examples, the re-sizing information can be included in IBECC re-sizing information 1010.

According to some examples, IBECC controller 1022-2 can re-size, based on the re-sizing information, the memory capacity to include reducing memory capacity included in the second region of the memory and adding memory capacity reduced from the second region of memory to the first region of the memory. For these examples, IBECC controller 1022-2 can implement a ballooning technique to re-size the memory capacity included in the first region of memory. Re-sized IBECC memory capacity 1035 can include instructions to the memory to re-size the memory capacity included in the first region of memory.

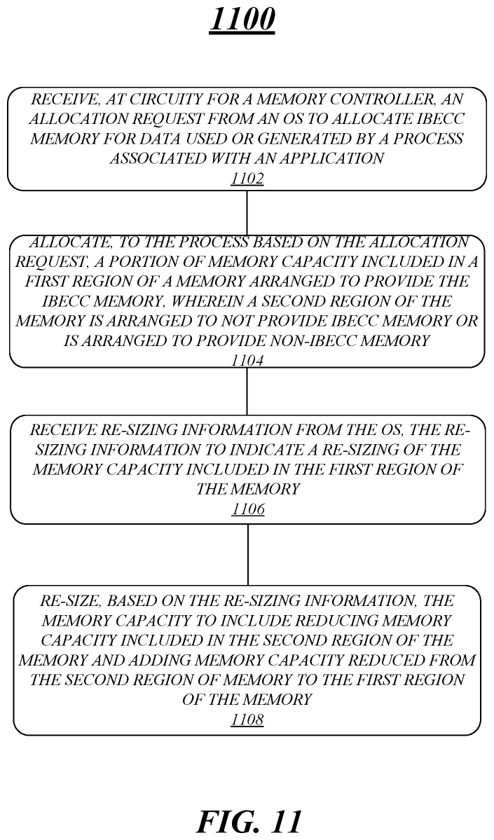

FIG. 11 illustrates an example logic flow 1100. Logic flow 1100 may be representative of some or all of the operations executed by one or more logic, features, or devices described herein, such as logic and/or features included in apparatus 1000. More particularly, logic flow 1100 can be implemented by one or more of receive logic 1022-1 or IBECC controller 1022-2.

In some examples, as shown in FIG. 11, logic flow 1100 at block 1102 can receive, at circuitry for a memory controller, an allocation request from an OS to allocate IBECC memory for data used or generated by a process associated with an application. For these examples, receive logic 1022-1 can receive the allocation request.

According to some examples, as shown in FIG. 11, logic flow 1100 at block 1104 can allocate, to the process based on the allocation request, a portion of memory capacity included in a first region of a memory arranged to provide the IBECC memory, wherein a second region of the memory is arranged to not provide IBECC memory or is arranged to provide non-IBECC memory. For these examples, IBECC controller 1022-2 can allocate the portion of memory capacity.

In some examples, as shown in FIG. 11, logic flow 1100 at block 1106 can receive re-sizing information from the OS, the re-sizing information to indicate a re-sizing of the memory capacity included in the first region of the memory. For these examples, receive logic 1022-1 can receive the re-sizing information.

According to some examples, as shown in FIG. 11, logic flow 1100 at block 1108 can re-size, based on the re-sizing information, the memory capacity to include reducing memory capacity included in the second region of the memory and adding memory capacity reduced from the second region of memory to the first region of the memory. For these example, IBECC controller 1022-2 can re-size the memory capacity.

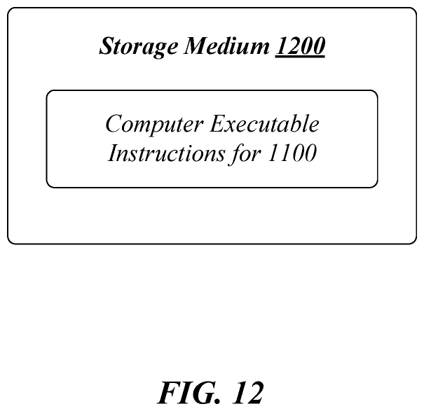

FIG. 12 illustrates an example of a storage medium. As shown in FIG. 12, the storage medium includes a storage medium 1200. The storage medium 1200 may comprise an article of manufacture. In some examples, storage medium 1200 can include any non-transitory computer readable medium or machine readable medium, such as an optical, magnetic or semiconductor storage. Storage medium 1200 can store various types of computer executable instructions, such as instructions to implement logic flow 1100. Examples of a computer readable or machine readable storage medium can include any tangible media capable of storing electronic data, including volatile memory or non-volatile memory, removable or non-removable memory, erasable or non-erasable memory, writeable or re-writeable memory, and so forth. Examples of computer executable instructions can include any suitable type of code, such as source code, compiled code, interpreted code, executable code, static code, dynamic code, object-oriented code, visual code, and the like. The examples are not limited in this context.

One or more aspects of at least one example can be implemented by representative instructions stored on a machine-readable medium which represents various logic within the processor, which when read by a machine causes the machine to fabricate logic to perform the techniques described herein. Such representations, known as “IP cores” can be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, various examples also include non-transitory, tangible machine-readable media containing instructions or containing design data, such as Hardware Description Language (HDL), which defines structures, circuits, apparatuses, processors and/or system features described herein. Such examples may also be referred to as program products.

In some cases, an instruction converter can be used to convert an instruction from a source instruction set to a target instruction set. For example, the instruction converter can translate (e.g., using static binary translation, dynamic binary translation including dynamic compilation), morph, emulate, or otherwise convert an instruction to one or more other instructions to be processed by the core. The instruction converter can be implemented in software, hardware, firmware, or a combination thereof. The instruction converter may be on processor, off processor, or part on and part off processor.

Various examples can be implemented using hardware elements, software elements, or a combination of both. In some examples, hardware elements can include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements can include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements can vary in accordance with any number of factors, such as desired computational rate, power levels, heat tolerances, processing cycle budget, input data rates, output data rates, memory resources, data bus speeds and other design or performance constraints, as desired for a given implementation.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The following examples pertain to additional examples of technologies disclosed herein.

Example 1. An example system can include a memory to be partitioned to include a first region arranged as IBECC memory and a second region arranged as non-IBECC memory. The system can also include a memory controller to include circuitry, the circuitry to receive an allocation request from an operating system to allocate IBECC memory for data used or generated by a process associated with an application. The circuitry can also allocate a portion of memory capacity included in the first region of the memory to the process based on the allocation request.

Example 2. The system of example 1, can also include the circuitry to receive re-sizing information from the operating system, the re-sizing information to indicate a re-sizing of the memory capacity included in the first region of the memory. The circuitry can also re-size, based on the re-sizing information, the memory capacity to include reducing memory capacity included in the second region of the memory and adding the memory capacity reduced from the second region of memory to the first region of the memory.

Example 3. The system of example 2, re-sizing information can include a size of memory capacity to remove from the second region of the memory and a memory address range of the memory associated with the size of memory capacity to remove from the second region of the memory.

Example 4. The system of example 3, to re-size the memory capacity of the first region of the memory can be based on allocated memory capacity reaching a threshold.

Example 5. The system of example 2, the circuitry may also include a plurality processing core and one or more punit registers configured to receive the re-sizing information from the operating system.

Example 6. The system of example 1, the circuitry can also receive re-sizing information from the operating system to indicate a re-sizing of the memory capacity included in the first region of the memory. The circuitry can also re-size, based on the re-sizing information, the memory capacity to include reducing memory capacity included in the first region of the memory and adding the memory capacity reduced from the first region of memory to the second region of the memory.

Example 7. The system of example 6, re-sizing information can include a size of memory capacity to remove from the first region of the memory and a memory address range of the memory associated with the size of memory capacity to remove from the first region of the memory.

Example 8. The system of example 7, to re-size the memory capacity of the first region of the memory can be based on allocated memory capacity to the second region of memory reaching a threshold.

Example 9. The system of example 6, the circuitry can also include a plurality processing cores and one or more punit registers configured to receive the re-sizing information from the operating system.

Example 10. An example at least one machine readable medium can include a plurality of instructions that in response to being executed by an operating system of a computing platform, can cause the operating system to receive information from an application to indicate that data used or generated by a process associated with the application is to be stored in IBECC memory. The instructions can also cause the operating system to generate, based on the information from the application, process control information for the process, the process control information to include an indication that the data used or generated by the process is to be stored in a first region of a memory arranged to provide IBECC memory. The instructions can also cause the operating system to cause a portion of memory capacity included in the first region of the memory to be allocated to the process.

Example 11. The at least one machine readable medium of example 10, the instructions can further cause the operating system to include, in the process control information, an indication of a memory address and a size for the portion of memory capacity to be allocated to the process. The instructions can also cause the operating system to send the memory address and size information to a memory controller for the memory to cause the portion of memory capacity to be allocated to the process.

Example 12. The at least one machine readable medium of example 10, the instructions can further cause the operating system to track memory capacity allocated to other processes associated with other application to have data used or generated by the other processes to be stored in IBECC memory provided by the first region of memory. The instructions can also cause the operating system to re-size a memory capacity of the first region of the memory based on allocated memory capacity reaching a threshold. The instructions can also cause the operating system to send re-sizing information to a memory controller for the memory to cause the memory capacity of the first region of memory to be re-sized.

Example 13. The at least one machine readable medium of example 12, to re-size the memory capacity of the first region of memory can also be based on free memory capacity in a second region of the memory, the second region of the memory is arranged to not provide IBECC memory or is arranged to provide non-IBECC memory.

Example 14. The at least one machine readable medium of example 13, the re-sizing information sent to the memory controller can indicate a memory capacity of the free memory capacity and a memory address range for the free memory capacity that is to be removed from the second region of the memory and added to the second region of the memory in order to re-size the first region of the memory to include an increased memory capacity to provide IBECC memory.

Example 15. An example apparatus may include one or more registers and circuitry. The circuitry can receive an allocation request from an operating system to allocate IBECC memory for data used or generated by a process associated with an application. The circuitry can also allocate, to the process based on the allocation request, a portion of memory capacity included in a first region of a memory arranged to provide the IBECC memory, wherein a second region of the memory is arranged to not provide IBECC memory or is arranged to provide non-IBECC memory.

Example 16. The apparatus of example 15 can also include the one or more registers configured to receive re-sizing information from the operating system. The re-sizing information can indicate a re-sizing of the memory capacity included in the first region of the memory. The apparatus can also include the circuitry configured to re-size, based on the re-sizing information to be received in the one or more registers, the memory capacity to include reducing memory capacity included in the second region of the memory and adding the memory capacity reduced from the second region of memory to the first region of the memory.

Example 17. The apparatus of example 16, the re-sizing information to be received in the one or more registers can include a size of memory capacity to remove from the second region of the memory and a memory address range of the memory associated with the size of memory capacity to remove from the second region of the memory.

Example 18. The apparatus of example 17, to re-size the memory capacity of the first region of the memory can be based on allocated memory capacity reaching a threshold.

Example 19. The example apparatus of example 15 can also include the one or more registers configured to receive re-sizing information from the operating system. The re-sizing information can indicate a re-sizing of the memory capacity included in the first region of the memory. The apparatus can also include the circuitry configured to re-size, based on the re-sizing information to be received in the one or more registers, the memory capacity to include reducing memory capacity included in the first region of the memory and adding the memory capacity reduced from the first region of memory to the second region of the memory.

Example 20. The apparatus of example 19, re-sizing information to be received in the one or more registers can include a size of memory capacity to remove from the first region of the memory and a memory address range of the memory associated with the size of memory capacity to remove from the first region of the memory.

Example 21. The apparatus of example 20, to re-size the memory capacity of the first region of the memory can be based on allocated memory capacity to the second region of memory reaching a threshold.

Example 22. An example method can include receiving, at circuitry for a memory controller, an allocation request from an operating system to allocate IBECC memory for data used or generated by a process associated with an application. The method can also include allocating, to the process based on the allocation request, a portion of memory capacity included in a first region of a memory arranged to provide the IBECC memory, wherein a second region of the memory is arranged to not provide IBECC memory or is arranged to provide non-IBECC memory.

Example 23. The method of example 22 can also include receiving re-sizing information from the operating system, the re-sizing information to indicate a re-sizing of the memory capacity included in the first region of the memory. The method can also include re-sizing, based on the re-sizing information, the memory capacity to include reducing memory capacity included in the second region of the memory and adding memory capacity reduced from the second region of memory to the first region of the memory.

Example 24. The method of example 23, re-sizing information can include a size of memory capacity to remove from the second region of the memory and a memory address range of the memory associated with the size of memory capacity to remove from the second region of the memory.

Example 25. The method of example 24, re-sizing the memory capacity of the first region of the memory can be based on allocated memory capacity reaching a threshold.

Example 26. The method of example 22 can also include receiving re-sizing information from the operating system to indicate a re-sizing of the memory capacity included in the first region of the memory. The method can also include re-sizing, based on the re-sizing information, the memory capacity to include reducing memory capacity included in the first region of the memory and adding the memory capacity reduced from the first region of memory to the second region of the memory.

Example 27. The method of example 26, re-sizing information can include a size of memory capacity to remove from the first region of the memory and a memory address range of the memory associated with the size of memory capacity to remove from the first region of the memory.

Example 28. The method of example 27, re-sizing the memory capacity of the first region of the memory can be based on allocated memory capacity to the second region of memory reaching a threshold.

Example 29. An example at least one machine readable medium can include a plurality of instructions that in response to being executed by a circuitry of a system can cause the circuitry to carry out a method according to any one of examples 22 to 28.

Example 30. An example apparatus can include means for performing the methods of any one of examples 22 to 28.

Example 31. An example method can include receiving information from an application to indicate that data used or generated by a process associated with the application is to be stored in IBECC memory. The method can also include generating, based on the information from the application, PCB for the process, the PCB to include a field to indicate the data used or generated by the process is to be stored in a first region of a memory arranged to provide IBECC memory. The method can also include causing a portion of memory capacity included in the first region of the memory to be allocated to the process.

Example 32. The method of example 31 can also include generating the PCB for the process to also include a second field to indicate a memory address and size information for the portion of memory capacity to be allocated to the process. The method can also include sending the memory address and size information to a memory controller for the memory to cause the portion of memory capacity to be allocated to the process.

Example 33. The method of example 31 may also include tracking memory capacity allocated to other processes associated with other application to have data used or generated by the other processes to be stored in IBECC memory provided by the first region of memory. The method can also include determining to re-size a memory capacity of the first region of the memory based on allocated memory capacity reaching a threshold. The method can also include sending re-sizing information to a memory controller for the memory to cause the memory capacity of the first region of memory to be re-sized.

Example 34. The method of example 33, determining to re-size the memory capacity of the first region of memory can also be based on free memory capacity in a second region of the memory, the second region of the memory is arranged to not provide IBECC memory or is arranged to provide non-IBECC memory.

Example 35. The method of example 34, the re-sizing information sent to the memory controller can indicate a memory capacity of the free memory capacity and a memory address range for the free memory capacity that is to be removed from the second region of the memory and added to the second region of the memory in order to re-size the first region of the memory to include an increased memory capacity to provide IBECC memory.

Example 36. An example at least one machine readable medium can include a plurality of instructions that in response to being executed by a system can cause the system to carry out a method according to any one of examples 31 to 35.

Example 37. An example apparatus can include means for performing the methods of any one of examples 31 to 35.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A system comprising:
a memory to be partitioned to include a first region arranged as in-band error correction control (IBECC) memory and a second region arranged as non-IBECC memory; and
a memory controller to include circuitry, the circuitry to:
receive an allocation request from an operating system to allocate IBECC memory for data used or generated by a process associated with an application; and
allocate a portion of memory capacity included in the first region of the memory to the process based on the allocation request.

2. The system of claim 1, further comprising the circuitry to:
receive re-sizing information from the operating system, the re-sizing information to indicate a re-sizing of the memory capacity included in the first region of the memory; and
re-size, based on the re-sizing information, the memory capacity to include reducing memory capacity included in the second region of the memory and adding the memory capacity reduced from the second region of memory to the first region of the memory.

3. The system of claim 2, wherein re-sizing information includes a size of memory capacity to remove from the second region of the memory and a memory address range of the memory associated with the size of memory capacity to remove from the second region of the memory.

4. The system of claim 3, wherein to re-size the memory capacity of the first region of the memory is based on allocated memory capacity reaching a threshold.

5. The system of claim 2, the circuitry further comprising:
a plurality processing cores; and
one or more punit registers configured to receive the re-sizing information from the operating system.

6. The system of claim 1, further comprising the circuitry to:
receive re-sizing information from the operating system to indicate a re-sizing of the memory capacity included in the first region of the memory; and
re-size, based on the re-sizing information, the memory capacity to include reducing memory capacity included in the first region of the memory and adding the memory capacity reduced from the first region of memory to the second region of the memory.

7. The system of claim 6, wherein re-sizing information includes a size of memory capacity to remove from the first region of the memory and a memory address range of the memory associated with the size of memory capacity to remove from the first region of the memory.

8. The system of claim 7, wherein to re-size the memory capacity of the first region of the memory is based on allocated memory capacity to the second region of memory reaching a threshold.

9. The system of claim 6, the circuitry further comprising:
a plurality processing cores; and
one or more punit registers configured to receive the re-sizing information from the operating system.

10. At least one machine readable medium comprising a plurality of instructions that in response to being executed by an operating system of a computing platform, causes the operating system to:
receive information from an application to indicate that data used or generated by a process associated with the application is to be stored in in-band error correction control (IBECC) memory;
generate, based on the information from the application, process control information for the process, the process control information to include an indication that the data used or generated by the process is to be stored in a first region of a memory arranged to provide IBECC memory; and
cause a portion of memory capacity included in the first region of the memory to be allocated to the process.

11. The at least one machine readable medium of claim 10, the instructions to further cause the operating system to:
include, in the process control information, an indication of a memory address and a size for the portion of memory capacity to be allocated to the process; and
send the memory address and size information to a memory controller for the memory to cause the portion of memory capacity to be allocated to the process.

12. The at least one machine readable medium of claim 10, the instructions to further cause the operating system to:
track memory capacity allocated to other processes associated with other application to have data used or generated by the other processes to be stored in IBECC memory provided by the first region of memory;
re-size a memory capacity of the first region of the memory based on allocated memory capacity reaching a threshold; and
send re-sizing information to a memory controller for the memory to cause the memory capacity of the first region of memory to be re-sized.

13. The at least one machine readable medium of claim 12, wherein to re-size the memory capacity of the first region of memory is also based on free memory capacity in a second region of the memory, the second region of the memory is arranged to not provide IBECC memory or is arranged to provide non-IBECC memory.

14. The at least one machine readable medium of claim 13, wherein the re-sizing information sent to the memory controller indicates a memory capacity of the free memory capacity and a memory address range for the free memory capacity that is to be removed from the second region of the memory and added to the second region of the memory in order to re-size the first region of the memory to include an increased memory capacity to provide IBECC memory.

15. An apparatus comprising:
one or more registers; and
circuitry to:
receive an allocation request from an operating system to allocate in-band error correction control (IBECC) memory for data used or generated by a process associated with an application; and
allocate, to the process based on the allocation request, a portion of memory capacity included in a first region of a memory arranged to provide the IBECC memory, wherein a second region of the memory is arranged to not provide IBECC memory or is arranged to provide non-IBECC memory.

16. The apparatus of claim 15, further comprising:
the one or more registers configured to receive re-sizing information from the operating system, the re-sizing information to indicate a re-sizing of the memory capacity included in the first region of the memory; and
the circuitry configured to re-size, based on the re-sizing information to be received in the one or more registers, the memory capacity to include reducing memory capacity included in the second region of the memory and adding the memory capacity reduced from the second region of memory to the first region of the memory.

17. The apparatus of claim 16, wherein the re-sizing information to be received in the one or more registers includes a size of memory capacity to remove from the second region of the memory and a memory address range of the memory associated with the size of memory capacity to remove from the second region of the memory.

18. The apparatus of claim 17, wherein to re-size the memory capacity of the first region of the memory is based on allocated memory capacity reaching a threshold.

19. The apparatus of claim 15, further comprising:
the one or more registers configured to receive re-sizing information from the operating system, the re-sizing information to indicate a re-sizing of the memory capacity included in the first region of the memory; and
the circuitry configured to re-size, based on the re-sizing information to be received in the one or more registers, the memory capacity to include reducing memory capacity included in the first region of the memory and adding the memory capacity reduced from the first region of memory to the second region of the memory.

20. The apparatus of claim 19, wherein re-sizing information to be received in the one or more registers includes a size of memory capacity to remove from the first region of the memory and a memory address range of the memory associated with the size of memory capacity to remove from the first region of the memory.

21. The apparatus of claim 20, wherein to re-size the memory capacity of the first region of the memory is based on allocated memory capacity to the second region of memory reaching a threshold.
